(19) United States
(12) Patent Application Publication
(10) Pub. No.: US 2026/0322386 A1
(43) Pub. Date: Oct. 15, 2026

(54) Switched-Capacitor Clock Synthesizer For Nonlinear Loads

(71) Applicant: Bitdeer, Inc., San Jose, CA (US)

(72) Inventor: Stephen M. Beccue, Salmon, ID (US)

(21) Appl. No.: 19/176,438

(22) Filed: Apr. 11, 2025

(51) Int. Cl. H03L 7/081

(52) U.S. Cl. CPC H03L 7/0812

(57) ABSTRACT

A switched-capacitor clock synthesizer includes a capacitor bank having a plurality of capacitors connected in series, between a power supply voltage Vdd and ground, a plurality of output switches on each capacitor that enables the generation of multiple output signals of various waveform types, and a plurality of order control switches that affect the order in which the plurality of capacitors are connected in series. Periodically changing the order in which the plurality of capacitors are connected in series results in each capacitor sourcing and sinking the same charge on average, making the switched-capacitor clock synthesizer well-suited for driving nonlinear loads, such as adiabatic logic gates and transmission gate logic.

### BACKGROUND OF THE INVENTION

Digital integrated circuits (ICs) are commonly fabricated using complementary metal-oxide-semiconductor (CMOS) technology. Given that CMOS logic gates dissipate large amounts of power, however, particularly when switching, other lower-power logic approaches have been proposed over the years. One approach known as “adiabatic logic” (i.e., “charge recovery logic”) operates with an oscillating power supply, often referred to as the “power clock” since it not only supplies power to the adiabatic logic but also because it controls the adiabatic logic system's timing. Typically, a four-phase trapezoidal power clock is used, as illustrated in FIG. 1, with each power clock phase φ₁, φ₂, φ₃ and φ₄ having evaluation (e), hold (h), charge recovery (r), and wait (w) intervals, and each configured to control one of four cascaded adiabatic logic gates 102, 104, 106 and 108.

During operation, when a first one of the adiabatic logic gates 102, 104, 106 or 108 in the chain is operating within the evaluation interval of its corresponding power clock phase, a second adiabatic gate just before it in the chain is operating in its hold interval, thereby giving the first adiabatic logic gate sufficient time to capture and use the second adiabatic logic gate's output as an input, and a third adiabatic logic gate in the chain just after the first adiabatic logic gate in the chain waits for its next evaluation interval to arrive, which occurs right after the evaluation interval of the first adiabatic gate ends. By ramping the power clock phases φ₁, φ₂, φ₃ and φ₄ up and down during the evaluation and charge recovery intervals, the maximum current flowing in the output networks of the adiabatic logic gates 102, 104, 106 and 108 during changes in output logic states is significantly reduced compared to the relatively higher currents that develop in the output networks of CMOS logic gates. The energy efficiency of the adiabatic logic gates 102, 104, 106 and 108 is therefore superior to CMOS logic gates. Charge stored in the output load capacitances of the adiabatic logic gates 102, 104, 106 and 108 is also recycled back to the energy reservoir of the power clock generator during the charge recovery intervals, further facilitating the energy efficiency of the adiabatic logic.

Because the power clock generator is an essential and indispensable part of any adiabatic logic circuit, it must be carefully designed so that it operates efficiently and does not undermine the energy savings gained by using adiabatic logic gates. A number of different power clock generators have been proposed. One approach utilizes a pair of differential inductor-capacitor (LC) resonant circuits (i.e., LC tank circuits) to generate a four-phase sinusoidal power clock and Schottky diodes to cut off the signal peaks of the sinusoids and thereby form the desired four-phase trapezoidal power clock waveforms. However, that approach is impractical since adiabatic logic, like all digital logic, is manufactured in ICs and inductors require very large integrated circuit areas.

Another approach that obviates the need for inductors is stepwise charging. FIG. 2 is a schematic drawing of one such inductor-less stepwise clock generator 200 known in the prior art. The stepwise clock generator 200 operates by sequentially switching tank capacitors 202-1, 202-2, . . . ,202-N to an output node OUT. Each tank capacitor 202-1, 202-2, . . . ,202-N, when switched to the output node OUT, injects a charge packet of size C_{L}(V_{DD}/N) onto the load 204, where C_{L} is the capacitance of the load capacitor 204 and V_{DD} is the generator's power supply voltage, thus raising the voltage across the load 204 incrementally by voltage steps of ΔV=V_{DD}/N. This process of sequentially switching the tank capacitor 202-1, 202-2, . . . ,202-N to the output node OUT thus forms a stepwise voltage ramp of increments ΔV=V_{DD}/N on the output node OUT, which ultimately plateaus at plateau voltage V_{DD}. The stepped-up waveform is then ramped back down by switching the tank capacitor 202-1, 202-2, . . . ,202-N in the reverse order, whereby all charge packets except for one are returned to (i.e., recovered by) the tank capacitors 202-1, 202-2, . . . ,202-N. It can be shown that the energy dissipated by the stepwise clock generator 200 over one complete cycle is equal to: E_{diss}=(C_{L}V²)/N. Charging the output load capacitor 204 in N steps instead of in a single step therefore reduces the energy dissipation by a factor of N.

At first glance the stepwise clock generator 200 would appear to be a suitable power clock generator for adiabatic logic, albeit being capable of only generating a single clock phase. However, in fact, it is not suitable. The problem is that adiabatic logic gates present themselves as nonlinear loads to power clock generators yet the stepwise clock generator 200 only works properly when driving a linear load, like load capacitor 204, for instance, which is a linear load. When an attempt is made to drive a nonlinear load the stepwise clock generator 200 produces a distorted output that undesirably takes on the transfer function of the nonlinear load, instead of it generating an output waveform with uniform voltage steps 208. The stepwise clock generator 200 is therefore unsuitable for driving adiabatic logic gates, or any other type of nonlinear load for that matter.

### BRIEF SUMMARY OF THE INVENTION

A switched-capacitor clock synthesizer includes a capacitor bank having a plurality of capacitors connected in series, between a power supply voltage Vdd and ground, a plurality of output switches on each capacitor that enables the generation of multiple output signals of various waveform types, and a plurality of order control switches that affect the order in which the plurality of capacitors are connected in series. Periodically changing the order in which the plurality of capacitors are connected in series results in each capacitor sourcing and sinking the same charge on average, making the switched-capacitor clock synthesizer well-suited for driving nonlinear loads, such as adiabatic logic gates and transmission gate logic.

Further features and advantages of the invention, including a detailed description of the above-summarized and other exemplary embodiments of the invention, will now be described in detail with respect to the accompanying drawings, in which like reference numbers are used to indicate identical or functionally similar elements.

### BRIEF DESCRIPTION OF THE DRAWINGS

FIG. 1 is a drawing illustrating the basic features of a conventional four-phase adiabatic logic system;

FIG. 2 is a schematic drawing of a stepwise clock generator known in the prior art and associated timing diagram;

FIG. 3 is a block diagram of a switched-capacitor clock synthesizer, according to one embodiment of the present invention;

FIG. 4 is a schematic drawing of a unit capacitor cell used to implement each of the unit capacitor cells of the switched-capacitor clock synthesizer depicted in FIG. 3, in accordance with one embodiment of the present invention;

FIG. 5 is a schematic drawing of transmission gate, a plurality of which are used to construct the unit capacitor cell depicted in FIG. 4, in accordance with one embodiment of the present invention;

FIG. 6 is a block diagram of a state machine that generates the switch control signals for the various switches in each of the unit capacitor cells of the switched-capacitor clock synthesizer depicted in FIG. 3, in accordance with one embodiment of the present invention;

FIG. 7 is a drawing depicting a series of snapshots of the switched-capacitor clock synthesizer depicted in FIG. 3, highlighting how its various switches are controlled in a process of generating one phase of a four-phase stepwise trapezoidal output signal;

FIG. 8 is a timing diagram of the stepwise trapezoidal output signal generated by the switched-capacitor clock synthesizer depicted in FIG. 3, for an implementation in which fifteen unit capacitor cells are configured in the loop, along with along with the output-switch control signals used in the generation process;

FIG. 9 is a schematic drawing of an ApplyVdd switch that is used to charge and periodically refresh the capacitors in the plurality of unit capacitor cells of the switched-capacitor clock synthesizer depicted in FIG. 3, in accordance with one embodiment of the present invention;

FIG. 10 is a timing diagram of four ninety-degree out-of-phase stepwise trapezoidal output signals generated by the switched-capacitor clock synthesizer depicted in FIG. 3, an ApplyVdd control signal that controls the operation of the ApplyVdd switch depicted in FIG. 9, and a sequence of ground-connect switch control signals SWG[1], SWG[2], SWG[3], which when applied to the switched-capacitor clock synthesizer cause the capacitors in the plurality of unit capacitor cells to effectively rotate around the loop, in accordance with one embodiment of the present invention; and

FIG. 11 is a drawing depicting a series of snapshots of the switched-capacitor clock synthesizer depicted in FIG. 3, highlighting how its various switches are controlled in a process of generating one phase of a four-phase stepwise trapezoidal output signal, and further highlighting how an order of the capacitors in the plurality of unit capacitor cells is changed by sequentially switching the ground-connect switches in the plurality of unit capacitor cells, in accordance with one embodiment of the present invention.

### DETAILED DESCRIPTION

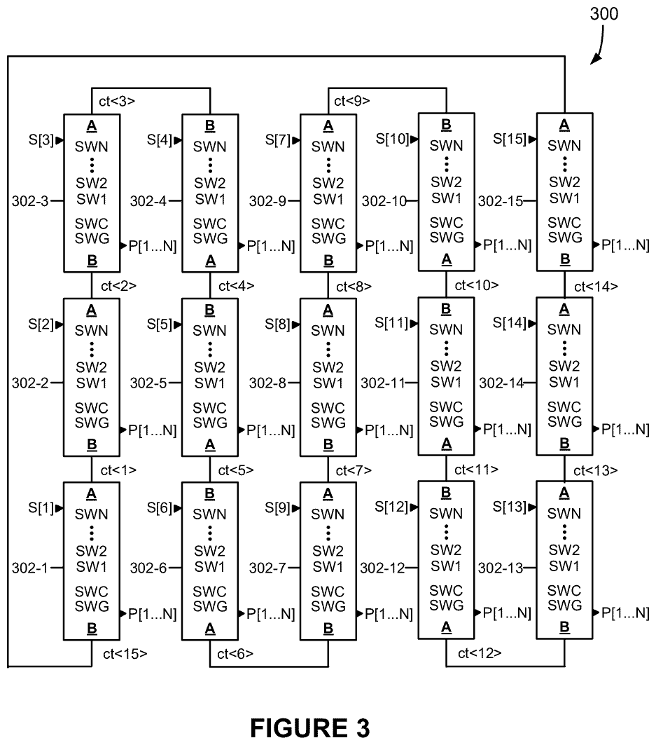

Referring to FIG. 3 there is shown a switched-capacitor clock synthesizer 300, according to one embodiment of the present invention. The switched-capacitor clock synthesizer 300 comprises a plurality of unit capacitor cells 302-1, 302-2, . . . ,302-M arranged in a loop, where M is an integer denoting the number of unit capacitor cells. In this example, there are M=15 unit capacitor cells 302-1, 302-2, . . . ,302-15 arranged in the loop but other numbers of unit capacitor cells may be used, as will be appreciated by those of ordinary skill in the art. Each of the unit capacitor cells 302-1, 302-2, . . . ,302-M has a first unit capacitor cell terminal (labeled “terminal A” in FIG. 3) and a second unit capacitor cell terminal (labeled “terminal B”), so that when configured in the loop terminal A of any given one of unit capacitor cells 302-1, 302-2, . . . ,302-M is coupled to terminal B of an adjacent unit capacitor cell. (Note: The terminal Bs are also labeled ct<1>, ct<2>, . . . ,ct<M> in FIG. 3.) Depending on the application, the switched-capacitor clock synthesizer 300 is operable to generate either a single stepwise output signal or, as indicated in FIG. 3, a plurality of stepwise output signals P[1], P[2], . . . ,P[N] of different phases, where N is an integer denoting the number of output signals generated. Finally, and as will be described in more detail below, each of the unit capacitor cells 302-1, 302-2, . . . ,302-M further comprises various internal switches that are controlled by M sets of switch control signals S[1], S[2], . . . ,S[M].

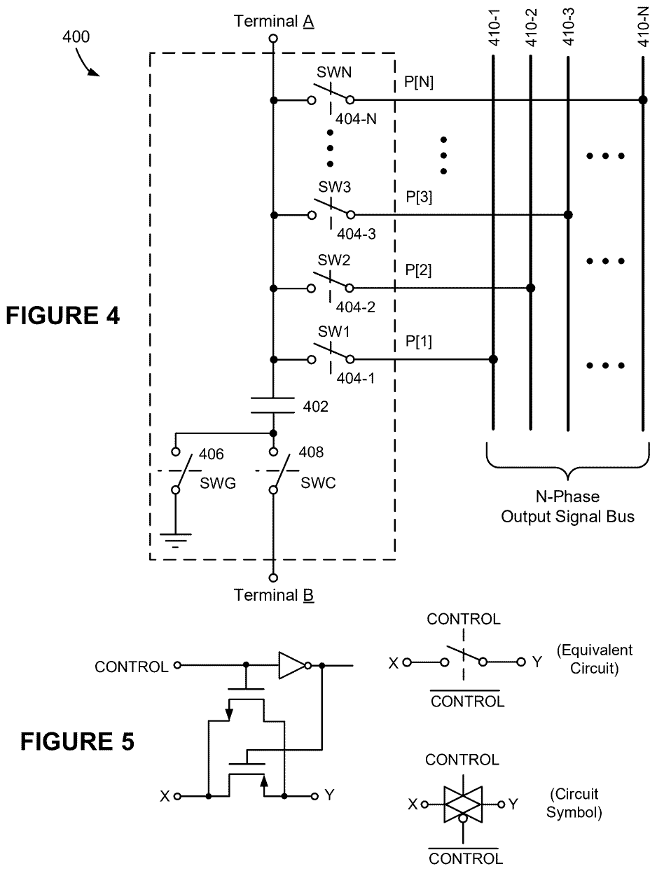

FIG. 4 is a schematic drawing illustrating how each of the unit capacitor cells 302-1, 302-2, . . . ,302-M is constructed in one embodiment of the present invention. The unit capacitor cell 400 comprises a capacitor 402; N output switches 404-1, 404-2, . . . ,404-N, where N is an integer denoting the number of signal outputs; a ground-connect switch 406; and a loop switch 408. A first terminal of capacitor 402 is connected to the first unit capacitor cell terminal (i.e., terminal A). An opposing second terminal of capacitor 402 is selectively coupled to the second unit capacitor cell terminal (i.e., terminal B), depending on whether loop switch 408 is open (i.e., is “off”) or closed (i.e., is “on”). The N output switches 404-1, 404-2, . . . ,404-N are coupled between the first terminal of capacitor 402 and N corresponding output signal buses 410-1, 410-2, . . . ,410-N or, alternatively between the second terminal of capacitor 402 and the N corresponding output signal buses 410-1, 410-2, . . . ,410-N, and the N output switches 404-1, 404-2, . . . ,404-N are controlled by N output-switch control signals SW1, SW2, . . . ,SWN. Ground-connect switch 406 is coupled between the second terminal of capacitor 402 and ground, and is controlled by ground-connect switch control signal SWG. Loop switch 408 is also connected to the second terminal of capacitor 402, and is controlled by loop-switch control signal SWC.

When ground-connect switch control signal SWG causes ground-connect switch 406 to close (second terminal of capacitor 402 connected to ground), loop-switch control signal SWC causes loop switch 408 to open and vice versa. Accordingly, when all of the unit capacitor cells 302-1, 302-2, . . . ,302-M of the switched-capacitor clock synthesizer 300 are constructed according to the exemplary unit capacitor cell 400 depicted in FIG. 4, the ground-connect switch 406 and loop switch 408 in each unit capacitor cell 302-1, 302-2, . . . ,302-M are neither closed at the same time nor open at the same time. Additionally, although any one of the unit capacitor cells 302-1, 302-2, . . . ,302-M can have its ground-connect switch 406 closed (depending on its corresponding ground-connect switch control signal SWG), only a single one of the unit capacitor cells 302-1, 302-2, . . . ,302-M has its associated ground-connect switch 406 closed at any given time. Together, the ground-connect switches 406[1], 406[2], . . . ,406[M] and loop switches 408[1], 408[2], . . . ,408[M] determine the order in which the capacitors 402[1], 402[2], . . . ,402[M] are connected in series between a power supply voltage Vdd and ground. For this reason, the ground-connect switches 406[1], 406[2], . . . ,406[M] and loop switches 408[1], 408[2], . . . ,408[M] may be collectively referred to as the “plurality of order control switches.”

The switches in the unit capacitor cells 302-1, 302-2, . . . ,302-M can be implemented in various ways. In one embodiment of the invention the switched-capacitor clock synthesizer 300 is fabricated in an IC and some or all of the switches are fabricated as transmission gates. A schematic diagram of one of the transmission gates is shown in FIG. 5, along with its equivalent circuit and commonly-used circuit symbol.

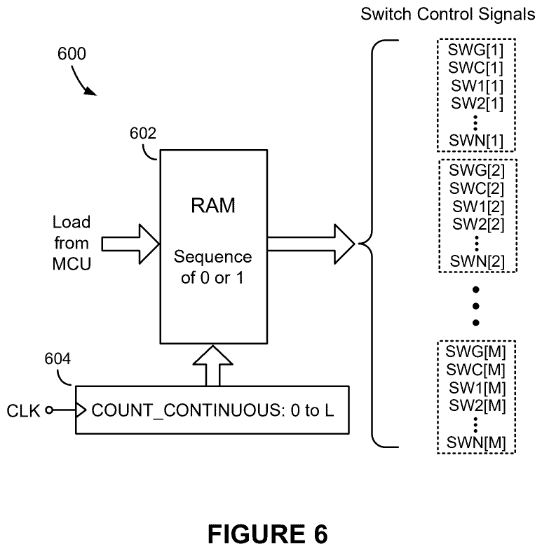

In accordance with one embodiment of the invention the M sets of switch control signals S[1], S[2], . . . ,S[M] for the plurality of unit capacitor cells 302-1, 302-2, . . . ,302-M, including switch control signals SWC, SWG and SW1, SW2, . . . ,SWN for each unit capacitor cell, are generated by a state machine. The state machine can be constructed in various ways but in general comprises a random access memory (RAM) 602 and a counter 604, as illustrated in FIG. 6. With the aid of the counter 604, the bit patterns of the switch control signals SWC, SWG and SW1, SW2, . . . ,SWN generated by an external microcontroller unit (MCU) are loaded into RAM 602 in a continuous sequence of length L. This is done for all unit capacitor cells 302-1, 302-2, . . . ,302-M. The RAM 602 and/or counter 604 can be fabricated in the same IC as the switched-capacitor clock synthesizer 300. Alternatively, either or both may be manufactured in one or more additional ICs, separate from the IC in which the switched-capacitor clock synthesizer 300 is manufactured.

The N output signal buses 410-1, 410-2, . . . ,410-N upon which the switched-capacitor clock synthesizer 300 generates the stepwise output signals P[1], P[2], . . . ,P[N] are shared by, in other words, are common among, the plurality of unit capacitor cells 302-1, 302-2, . . . ,302-M. However, whether the capacitor 402 of any given unit capacitor cell 302-1, 302-2, . . . or 302-M contributes to the stepwise formation of any of the stepwise output signals P[1], P[2], . . . ,P[N] is determined by whether any of its associated output switches 404-1, 404-2, 404-3, . . . ,404-N is open or closed and connected to any one of the N output signal bases. This attribute of the switched-capacitor clock synthesizer 300, together with the state machine's 600's ability to control and adjust the individual timing and phase relationships among the output-switch control signals SW1, SW2, . . . ,SWN for each unit capacitor cell 302-1, 302-2, . . . ,302-M, affords the switched-capacitor clock synthesizer 300 the ability to generate stepwise output signals P[1], P[2], . . . ,P[N] of essentially any waveform type. For example, it is fully capable of generating four (N=4) ninety-degree phase-offset stepwise trapezoidal output signals. This particular capability, together with the switched-capacitor clock synthesizer's 300's ability to drive nonlinear loads, makes the switched-capacitor clock synthesizer 300 well-suited for service as a power clock generator in adiabatic logic systems.

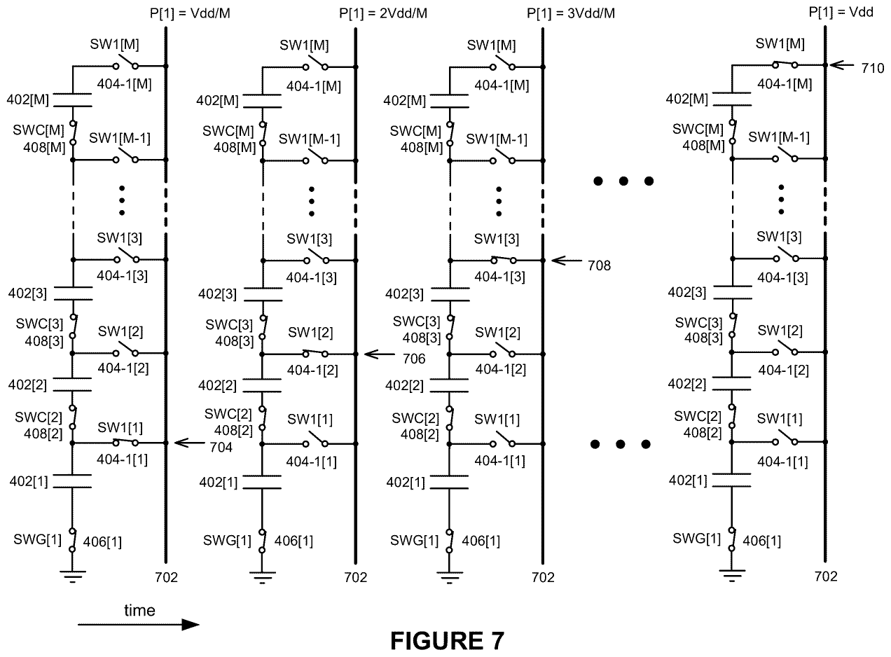

FIG. 7 highlights this capability and further illustrates the basic operation of the switched-capacitor clock synthesizer 300. The drawing depicts in a series of snapshots how the various switches in the switched-capacitor clock synthesizer 300 are controlled in the process of generating a single one of a four-phase stepwise trapezoidal output, namely first-phase output signal P[1], on first-phase output signal bus 702 (corresponding to first-phase output signal bus 410-1 in FIG. 4). In this exemplary series of snapshots unit capacitor cell 302-1 serves as the ground reference (see FIG. 3), its ground-connect switch 406[1] remaining closed, by control of its ground-connect switch control signal SWG[1], during the entire time the stepwise trapezoidal output signal P[1] is being generated. Meanwhile, and also during the entire time output signal P[1] is being generated, all of remaining ground-connect switches 406[2], 406[3], . . . ,406[M] (not shown) in all of remaining unit capacitor cell 302-2, 302-3, . . . ,302-M are controlled to remain open and loop switches 408[2], 408[3], . . . ,408[M] are all controlled to remain closed. Although not shown in FIG. 7, it is understood that: 1) loop switch 408[1] in unit capacitor cell 302-1 is controlled to remain open during the entire time the stepwise trapezoidal output signal P[1] is being generated, by control of its loop-connect switch control signal SWC[1]; 2) Terminal B of unit capacitor cell 302-1 is connected to Terminal A of unit capacitor cell 302-M for the duration; and 3) Terminal A of unit capacitor cell 302-M is coupled to Vdd. Hence, the only switches that are opened and closed during the generation of the stepwise trapezoidal output signal P[1] are output switches 404-1[1], 404-1[2], . . . ,404-1[M], which are controlled by output-switch control signals SW1[1], SW1[2], . . . ,SW1[M], respectively.

As can be seen in FIG. 7, with ground-connect switch 406[1] and loop switches 408[2], 408[3], . . . ,408[M] all closed, the plurality of capacitors 402[1], 402[2], . . . ,402[M] form what may be referred to as a “capacitor bank.” The capacitor bank is charged and periodically refreshed by an external power supply having a power supply voltage Vdd. Accordingly, a voltage Vdd is optimally maintained across the capacitor bank and each capacitor 402[1], 402[2], . . . ,402[M] within the capacitor bank optimally maintains a voltage drop across it of Vdd/M.

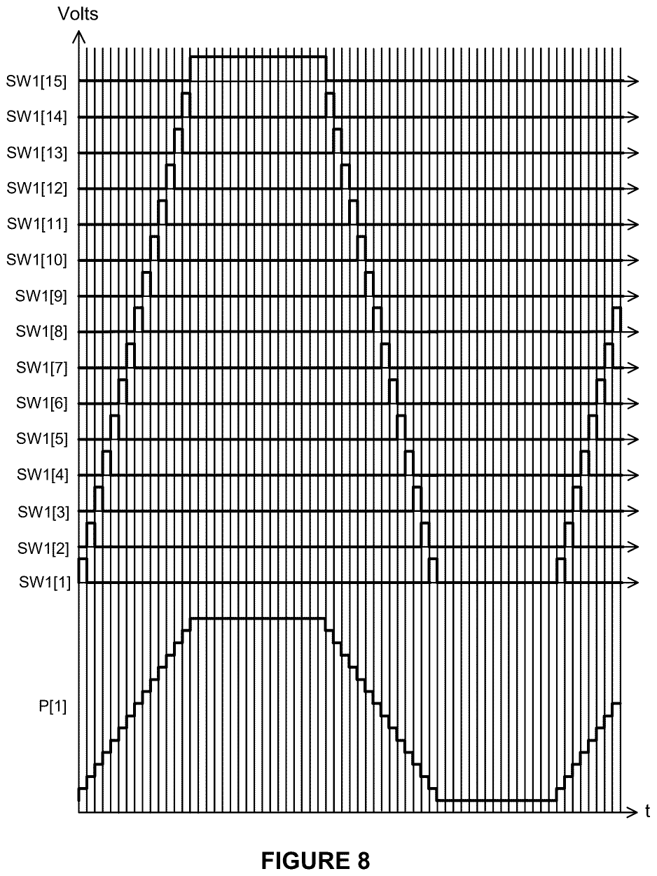

Generating the stepwise trapezoidal output signal P[1] on first-phase output signal bus 702 commences by closing the first-phase output switch closest to ground, namely first-phase output switch 404-1[1], as indicated by reference arrow 704 in FIG. 7. Closing the first-phase output switch 404-1[1] causes the voltage Vdd/M across capacitor 402[1] to be applied to first-phase output signal bus 702, thereby generating the first voltage step of the stepwise trapezoidal output signal P[1]. The remaining (M−1) first-phase output switches 404-1[2], 404-1[3], . . . ,404-1[M] are then closed and opened in sequence, as indicated by reference arrows 706, 708 and 710, thereby cumulatively increasing the number of unit capacitors 402[1], 402[2], 402[3], etc. coupled in series between first-phase output signal bus 702 and ground. The voltage on first-phase output signal bus 702 therefore progressively increases in voltage steps of Vdd/M, until the first-phase output switch nearest Vdd, namely first-phase output switch 404-1[M], is closed (as indicated by reference arrow 710) and the plateau voltage Vdd of the stepwise trapezoidal output signal P[1] is reached. First-phase output switch 404-1[M] is then held closed for a quarter cycle, after which time first-phase output switches 404-1[1], 404-1[2], 404-1[3], . . . ,404-1[M−1] are then sequentially closed and opened but in a reverse order from that in the ramp-up quarter cycle, thereby progressively subtracting the number of unit capacitors 402[] that are coupled in series between first-phase output signal bus 702 and ground and incrementally ramping down the voltage on first-phase output signal bus 702 in voltage steps of Vdd/M until a valley voltage of Vdd/M is reached. Finally, the first-phase output switch closest to ground, namely first-phase output switch 404-1[1], remains closed for a quarter cycle to complete the first full cycle of the stepwise trapezoidal output signal P[1]. The process described above repeats indefinitely, thereby producing the desired continuous stepwise trapezoidal output signal P[1] on first-phase output signal bus 702. FIG. 8 is a timing diagram showing the resulting stepwise trapezoidal output signal P[1] for the case when M=15, along with the output-switch control signals SW1[1], SW1[2], . . . ,SW1[15] that control the sequential closing and opening of first-phase output switches 404-1[1], 404-1[2], 404-1[3], . . . ,404-1[15].

The remaining three stepwise trapezoidal output signals P[2], P[3] and P[4] can be generated using a substantially similar process, the only major difference being that the second set of output-switch control signals SW2[1], SW2[2], . . . SW2[M] that control the operation of the second-phase output switches 404-2[1], 404-2[2], . . . ,404-2[M], the third set of output-switch control signals SW3[1], SW3[2], . . . SW3[M] that controls the operation of the third-phase output switches 404-3[1], 404-3[2], . . . ,404-3[M], and the fourth set of output-switch control signals SW4[1], SW4[2], . . . SW4[M] that controls the operation of the fourth-phase output switches 404-4[1], 404-4[2], . . . ,404-4[M], is each progressively delayed by a quarter period (i.e., by ninety degrees). The quarter cycle phase shifts among the first, second, third and fourth sets of output-switch control signals SW1[1], SW1[2], . . . SW1[M]; SW2[1], SW2[2], . . . SW2[M]; SW3[1]; SW3[2], . . . SW3[M]; and SW4[1], SW4[2], . . . SW4[M] are easily synthesized by appropriate programming of the MCU and loading of the resulting switch control bit patterns in the RAM 602 of the state machine 600.

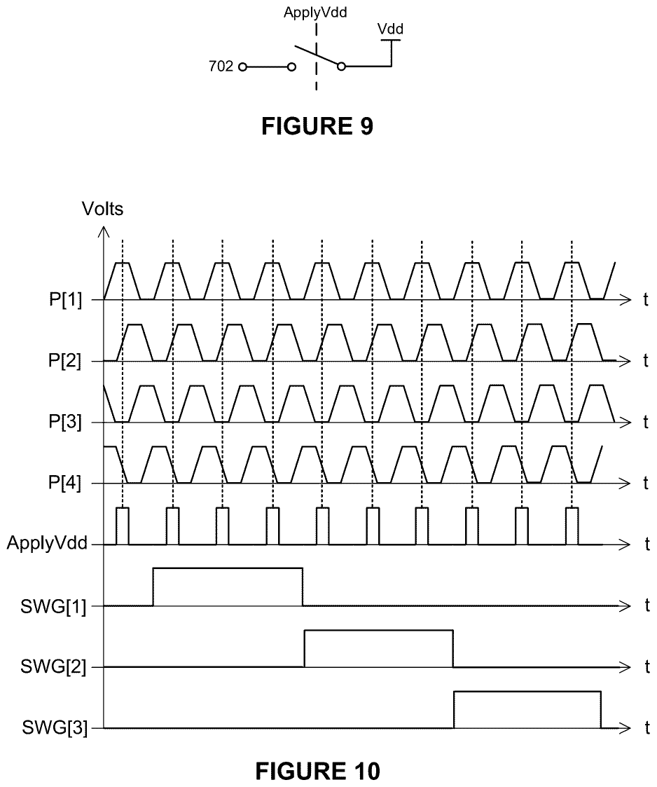

As was alluded to above, the capacitor bank formed from capacitors 402[1], 402[2], . . . ,402[M] in the plurality of unit capacitor cells 302-1, 302-2, . . . ,302-M is charged and periodically refreshed by an external power supply. In one embodiment of the invention, the power supply voltage Vdd is selectively and periodically applied to the capacitor bank of the switched-capacitor clock synthesizer 300 via an “ApplyVdd” switch 902 (see FIG. 9). A first terminal of the ApplyVdd switch 902 is coupled to one of the synthesizer's 300's output signal buses 410-1, 410-2, . . . ,410-N (first-phase output signal bus 702 (corresponding to output signal bus 410-1 in FIG. 4), for example) and a second terminal is connected to Vdd. The ApplyVdd switch 902 is controlled by a periodic ApplyVdd switch control signal that causes the ApplyVdd switch 902 to close during times when the output signal on the associated output signal bus is at Vdd. This timing relationship between the ApplyVdd switch control signal and output signal P[1] (assuming here that it is the first-phase output signal bus that the first terminal of the ApplyVdd switch is connected to) is shown in the timing diagram in FIG. 10, where it is seen that the ApplyVdd switch control signal is high (each time causing ApplyVdd switch 902 to close) only during times the output signal P[1] is at its plateau voltage Vdd. In another embodiment of the invention, each capacitor 402[1], 402[2], . . . ,402[M] is individually recharged via a plurality of ApplyVdd switches connected to the terminals A of the plurality of unit capacitor cells 302-1, 302-2, . . . ,302-M. However, this latter approach is less desirable since it requires M switches whereas the former only requires the single ApplyVdd switch 902.

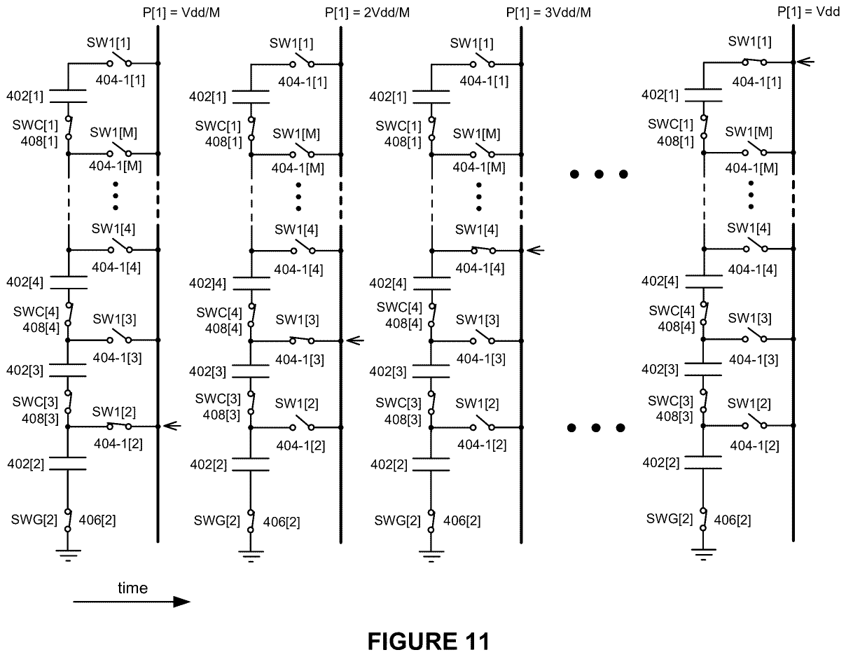

One very important attribute of the switched-capacitor clock synthesizer 300 is that it is capable of changing the order in which the capacitors 402[1], 402[2], . . . ,402[M] in the plurality of unit capacitor cells 302-1, 302-2, . . . ,302-M are configured between Vdd and ground. Changing the order is effected by which ground-connect switch 406[1], 406[2], . . . or 406[M] is closed. FIG. 11 illustrates, for example, how when ground-connect switch 406[2] is closed the capacitors in the plurality of unit capacitor cells 302-1, 302-2, . . . ,302-M have an order from ground to Vdd of: {402[2], 402[3], 402[4] . . . , 402[M], 402[1]}. This order is different from that when ground-connect switch 406[1] is closed, as in FIG. 7. In that case ground-connect switch 406[1] is closed instead and the capacitors in the plurality of unit capacitor cells 302-1, 302-2, . . . ,302-M have an order from ground to Vdd of: {402[1], 402[2], 402[3], . . . ,402[M−1], 402[M]}.

When the plurality of unit capacitor cells 302-1, 302-2, . . . ,302-M is configured in a loop (as in FIG. 3), sequentially closing the ground-connect switches (as ground-connect switches SWG[1], SWG[2] and SWG[3] are in FIG. 10, for example) effectively rotates the capacitors 402[1], 402[2], . . . ,402[M] in the plurality of unit capacitor cells 302-1, 302-2, . . . ,302-M around the loop. Note that the capacitors 402[1], 402[2], . . . ,402[M] could alternatively be randomly reordered by randomly selecting which one of the ground-connect switches 406[1], 406[2], . . . or 406[M] is closed, and the switched-capacitor clock synthesizer 300 would continue to operate properly so long as the shuffling of the voltage levels on the ct<> nodes is taken into consideration.

Periodically reordering the capacitors 402[1], 402[2], . . . ,402[M] results in each capacitor sourcing and sinking the same charge on average, even though the charge at each step of the stepwise generation process may be different. This allows the switched-capacitor clock synthesizer 300 to produce uniform voltage steps even when driving nonlinear loads, such as adiabatic logic and transmission gate logic, for example.

One consequence of coupling the capacitors in series is that output impedance of the switched-capacitor clock synthesizer 300 is high (M/jωC). In one embodiment of the invention the high output impedance can lowered by selectively connecting (using the SWG control, for example) an impedance-lowering capacitor to the node in the capacitor bank where the voltage is Vdd/2. By maintaining this single impedance-lowering capacitor at the Vdd/2 node, the capacitive reactance at that node is lowered from M/2ωC to M/2ωC||1/ωC, which is a dramatic improvement. A similar approach can be done on one or more other nodes of the synthesizer's 300's capacitor bank.

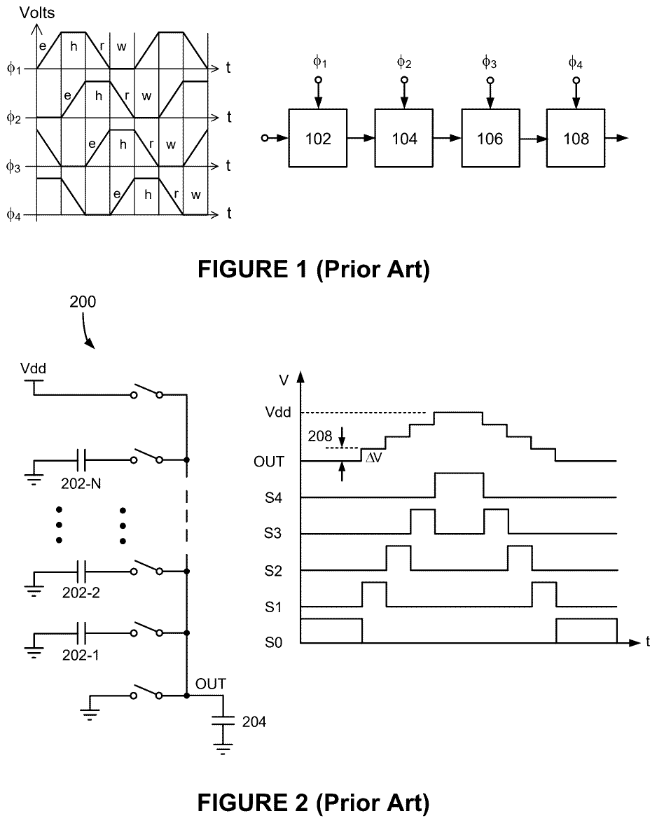

Finally, whereas the foregoing detailed description is illustrative in highlighting the utility of the switched-capacitor clock synthesizer 300 at driving nonlinear loads, in particular N=4 adiabatic logic gates in a four-phase adiabatic logic system (like that depicted in FIG. 1), it should be understood that the switched-capacitor clock synthesizer 300 is also suitable for other applications, whether the load be linear or nonlinear, and that the switched-capacitor clock synthesizer 300 can be adapted and configured to generate, depending on whatever the need or requirement may be, any number N of output signals. Moreover, it should be emphasized and understood from the foregoing detailed description that the phase shifts among consecutive phases of the various output signals produced by the switched-capacitor clock synthesizer 300 need not be, necessarily, equal, as the switched-capacitor clock synthesizer 300 can be easily adapted to produce essentially any phase relationship among its N output signals and realized by simple adaptation of the state machine 600 to a given application or minor modification of the state machine 600 to fulfill whatever phase relationships may be needed or desired for the given application.

While various embodiments of the present invention have been described, they have been presented by way of example and not limitation. It will be apparent to persons skilled in the relevant art that various changes in form and detail may be made to the exemplary embodiments without departing from the true spirit and scope of the invention. Accordingly, the scope of the invention should not be limited by the specifics of the exemplary embodiments but, instead, should be determined by the appended claims, including the full scope of equivalents to which such claims are entitled.

1-6. (canceled)

7. A switched-capacitor clock synthesizer, comprising:
a plurality of capacitors coupled in series between a power supply voltage Vdd and ground;
a first-phase output signal bus;
a plurality of first-phase output switches configured and controlled to selectively couple capacitors in the plurality of capacitors to the first-phase output signal bus; and
a plurality of switches that control an order in which the plurality of capacitors is coupled in series,
wherein the switches in the plurality of first-phase output switches are controlled to:
switch closed and open in sequence, starting with the first-phase output switch closest to ground, to thereby produce a stepwise voltage ramp up on the first-phase output signal bus with incrementing voltage steps of Vdd/M, where M denotes the number of capacitors in the plurality of capacitors,
and subsequently switch closed and open in a reverse sequence, starting with the first-phase output switch closest to Vdd, to thereby produce a stepwise voltage ramp down on the first-phase output signal bus with decrementing voltage steps of Vdd/M.

8. (canceled)

9. The switched-capacitor clock synthesizer of claim 7, wherein the plurality of capacitors is arranged in a loop, and the plurality of switches that controls the order in which the plurality of capacitors is coupled in series comprises a plurality of loop switches configured to control which capacitor among the plurality of capacitors is disconnected from the loop and has a terminal coupled to Vdd and a plurality of ground-connect switches configured to control which capacitor among the plurality of capacitors has a terminal coupled to ground.

10. The switched-capacitor clock synthesizer of claim 9, wherein the plurality of loop switches and the plurality of ground-connect switches are configured and sequentially controlled so as to effectively rotate the plurality of capacitors around the loop and alter the order in which the plurality of capacitors is coupled in series.

11. The switched-capacitor clock synthesizer of claim 9, wherein the plurality of loop switches and the plurality of ground-connect switches are configured and controlled to randomly alter the order in which the plurality of capacitors is coupled in series.

12. The switched-capacitor clock synthesizer of claim 7, further comprising an ApplyVdd switch coupled between a power supply voltage terminal and the first-phase output signal bus through which the plurality of capacitors is periodically recharged when both it and the switch in the plurality of first-phase output switches that is closest to the power supply voltage Vdd are both closed.

13. The switched-capacitor clock synthesizer of claim 7, further comprising a plurality of ApplyVdd switches coupled between a power supply voltage terminal and the plurality of first terminals of the plurality of capacitors through which the plurality of capacitors is periodically recharged.

14. The switched-capacitor clock synthesizer of claim 7, further comprising:
a plurality of second-phase output switches configured and controlled to selectively couple capacitors in the plurality of capacitors to a second-phase output signal bus;
a plurality of third-phase output switches configured and controlled to selectively couple capacitors in the plurality of capacitors to a third-phase output signal bus; and
a plurality of fourth-phase output switches configured and controlled to selectively couple capacitors in the plurality of capacitors to a fourth-phase output signal bus.

15. The switched-capacitor clock synthesizer of claim 14, wherein the switches in each plurality of first-phase, second-phase, third-phase and fourth-phase output switches are:
switched closed and open in a sequence, starting with the output switch in each plurality of first-phase, second-phase, third-phase and fourth-phase output switches that is closest to ground, and
switched closed and open in a reverse sequence, starting with the output switch in each plurality of first-phase, second-phase, third-phase and fourth-phase output switches that is closest to the power supply voltage Vdd,
to thereby produce four phase-offset stepwise voltage waveforms on the first-phase, second-phase, third-phase and fourth-phase output signal buses.

16. The switched-capacitor clock synthesizer of claim 15, wherein the switches in the pluralities of first-phase, second-phase, third-phase and fourth-phase output switches are configured and controlled so that the four phase-offset stepwise voltage waveforms produced on the first-phase, second-phase, third-phase and fourth-phase output signal buses are ninety degrees out of phase relative to one another.

17. The switched-capacitor clock synthesizer of claim 15, wherein the switches in the pluralities of first-phase, second-phase, third-phase and fourth-phase output switches are configured and controlled so that consecutive phases of the four phase-offset stepwise voltage waveforms produced on the first-phase, second-phase, third-phase and fourth-phase output signal buses have phase shifts of less than ninety degrees.

18. The switched-capacitor clock synthesizer of claim 15, wherein the switches in the pluralities of first-phase, second-phase, third-phase and fourth-phase output switches are configured and controlled so that a first phase shift between two consecutive phases of the four phase-offset stepwise voltage waveforms is different from a second phase shift among two other consecutive phases of the four phase-offset stepwise voltage waveforms.

19. The switched-capacitor clock synthesizer of claim 7, further comprising an impedance-lowering capacitor that is selectively coupled to a series midpoint of the plurality of capacitors, the series midpoint depending on the order in which the plurality of capacitors are coupled in series.

20-24. (canceled)

25. A method of synthesizing a stepwise voltage waveform, comprising:
forming a capacitor bank by coupling a plurality of capacitors in series;
periodically charging the capacitor bank from a power supply so that each capacitor in capacitor bank optimally maintains a constant voltage Vdd/M across it, where M denotes the number of capacitors in the capacitor bank and Vdd denotes the power supply voltage;
stepping up a voltage on an output node by cumulatively coupling capacitors from the capacitor bank to the output node;
stepping down the output voltage on the output node by coupling said capacitors to the output node in a sequence opposite to that by which they were cumulatively coupled to the output node; and
synthesizing a periodic stepwise voltage waveform on the output node by repeating the stepping up and stepping down steps.

26. The method of claim 25, further comprising, changing over time an order in which the capacitors in the capacitor bank are coupled in series.

27. A switched-capacitor clock synthesizer, comprising:
a plurality of capacitors coupled in series between a power supply voltage Vdd and ground;
a first-phase output signal bus;
a plurality of first-phase output switches configured and controlled to selectively couple capacitors in the plurality of capacitors to the first-phase output signal bus;
a plurality of switches that control an order in which the plurality of capacitors is coupled in series; and
an ApplyVdd switch coupled between a power supply voltage terminal and the first-phase output signal bus through which the plurality of capacitors is periodically recharged when both it and the switch in the plurality of first-phase output switches that is closest to the power supply voltage Vdd are both closed.

28. A switched-capacitor clock synthesizer, comprising:
a plurality of capacitors coupled in series between a power supply voltage Vdd and ground;
a first-phase output signal bus;
a plurality of first-phase output switches configured and controlled to selectively couple capacitors in the plurality of capacitors to the first-phase output signal bus;
a plurality of switches that control an order in which the plurality of capacitors is coupled in series; and
an impedance-lowering capacitor that is selectively coupled to a series midpoint of the plurality of capacitors, the series midpoint depending on the order in which the plurality of capacitors are coupled in series.
